(19) United States
(12) Patent Application Publication
(10) Pub. No.: US 2006/0138444 A1
(43) Pub. Date: Jun. 29, 2006

(54) Flip-chip bonding structure of light-emitting element using metal column

(75) Inventors: Won-kyoung Chio, Suwon-si (KR); Tae-hoon Jang, Seoul (KR); Su-hee Chae, Suwon-si (KR); Hyung-kun Kim, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electro-Mechanics Co., Ltd., Suwon-si (KR)

(21) Appl. No.: 11/220,696

(22) Filed: Sep. 8, 2005

(30) Foreign Application Priority Data
Dec. 29, 2004 (KR) 10-2004-0115070

(51) Int. Cl. H01L 29/24

(52) U.S. Cl. 257/100

(57) ABSTRACT

A flip-chip bonding structure of a light-emitting element is provided. The structure improves a heat emission efficiency by using a metal column having a high thermal conductivity instead of a solder bump. The structure includes a light-emitting element, a sub-mount, and a metal column. The metal column connects the light-emitting element with the sub-mount electrically and thermally.

### CROSS-REFERENCE TO RELATED PATENT APPLICATION

This application claims the benefit of Korean Patent Application No. 10-2004-0115070, filed on Dec. 29, 2004, in the Korean Intellectual Property Office, the disclosure of which is incorporated herein in its entirety by reference.

### BACKGROUND OF THE DISCLOSURE

1. Field of the Disclosure The disclosure relates to a flip-chip bonding structure of a light-emitting element using a metal column, and more particularly, to a flip-chip bonding structure of a light-emitting element capable of improving the heat emission efficiency by using a metal column of a large thermal conductivity instead of a solder bump.

2. Description of the Related Art

As illustrated in FIG. 1, a wire-bonding has been primarily used in bonding light-emitting elements such as a laser diode (LD) or a light-emitting diode (LED) to a package. That is, an operation current and voltage are applied by connecting both ends of wires 150a and 150b to respective electrodes 122 and 126 of the light-emitting element and pads of the package (not shown), respectively.

However, as the degree of integration of a chip that includes the light-emitting element is raised, the length of the wire for connecting the light-emitting element with the package is lengthened. Generally, since the line resistance of the wire is proportional to its length, the line resistance increases as its length increases. Further, as the requirement for a light-emitting element of high power is growing, the operation voltage is raised and thus heat generated from a ridge of the light-emitting element is increased. Since this heat is emitted through a wire or surrounding air in a wire-bonding structure, the heat is not effectively emitted, so a new bonding structure for the light-emitting element is needed. Accordingly, a necessity for a new bonding technology capable of replacing a related art wire bonding technology emerges and a flip-chip bonding method for connecting the light-emitting element with a sub-mount using a solder bump, has been suggested.

FIG. 2 is a view illustrating a light-emitting element that is bonded to a sub-mount using the flip-chip bonding method of a related art.

As illustrated in FIG. 2, a light-emitting element 120 is formed on a sapphire substrate 110 and two metal pad layers 128a and 128b are formed on a surface of the light-emitting element 120, respectively. The two metal pad layers 128a and 128b are connected with a p-type electrode 126 and an n-type electrode 122 of the light-emitting element 120, respectively. Further, solder bumps 140a and 140b of Sn-series made of material such as SnAg, PbSn, and AuSn are formed on the two metal pad layers 128a and 128b. On the solder bumps 140a and 140b, another two metal pad layers 135a and 135b are formed, respectively. A sub-mount 130 that includes AlN for example is positioned on the metal pad layers 135a and 135b. Here, for the light-emitting element 120, a semiconductor laser diode made of nitrides of GaN-series can be used for example. In that case, light is emitted through a ridge 125 to a direction perpendicular to the drawing.

Although it appears that the metal pad layers 128a and 128b, the solder bumps 140a and 140b, the metal pad layers 135a and 135b, and the sub-mount 130 are sequentially stacked on the light-emitting element 120 in FIG. 2, actually the light-emitting element 120 where the metal pad layers 128a and 128b are formed is connected with the sub-mount 130 where the metal pad layers 135a and 135b are formed using the solder bumps 140a and 140b. Here, the metal pad layers 128a and 128b and the metal pad layers 135a and 135b are intended for improving an adhesive efficiency with respect to the solder bumps 140a and 140b. For example, the metal pad layers can be prepared by consecutively stacking a Ti-film, a Pt-film, and an Au-film. Though not shown, a platinum diffusion prevention film for preventing Sn within the solder bumps from diffusing to the metal pad layers 128a and 128b can be interposed between the solder bumps 140a and 140b and the metal pad layers 128a and 128b.

With the above-described structure, the light-emitting element is directly connected with the sub-mount through the solder bumps without a wire, whereby heat and current delivery paths are remarkably reduced and the heat emission area is increased. Therefore, the heat emission efficiency is increased and the resistance is reduced.

In a bonding structure of a related art that uses the solder bump, the low thermal conductivity of the solder bump is problematic. For example, the thermal conductivity of SnAg currently utilized is merely 33 mK/cm² and a thermal conductivity of a solder bump made of PbSn is 50 mK/cm². Further, even in the case of a solder bump made of one whose thermal conductivity is the greatest among the Sn-series, the thermal conductivity is only 70 mK/cm². The thermal conductivity of a commonly used solder bump does not exceed 70 mK/cm². On the contrary, in case AlN is used for the sub-mount, the thermal conductivity of the sub-mount which is a heat sink is about 250 mK/cm², which is far greater than that of the solder bump. Therefore, in when bonding using a solder bump, the thermal conductivity is gradually increased along a heat emission path from a heat source to the final heat emission point, so that the heat emission efficiency is diminished. Recently, as heat generation is increased and the temperature is raised due to the high power trend of the light-emitting elements such as semiconductor laser diode, the low thermal conductivity of the solder bump emerges as a severe problem.

### SUMMARY OF THE DISCLOSURE

The present invention may provide a flip-chip bonding structure of a light-emitting element capable of improving the heat emission efficiency by using a metal column of a large thermal conductivity instead of a solder bump.

The present invention may also provide a flip-chip bonding structure of a light-emitting element, which includes a light-emitting element, a sub-mount, and a metal column for connecting the light-emitting element with the sub-mount electrically and thermally.

According to the present invention, the thermal conductivity of the metal column is greater than that of the sub-mount. For that purpose, the metal column is made of at least one metal selected from the group consisting of Au, Ag, and Cu.

Also, metal pad layers for improving adhesive efficiency with respect to the metal column can be further provided between the light-emitting element and the metal column, and between the sub-mount and the metal column. The metal pad layer between the light-emitting element and the metal column is electrically connected with an electrode of the light-emitting element.

According to the present invention, the metal column can be directly bonded to the sub-mount using a sonic bonding method. Alternatively, the metal column can be bonded to the sub-mount using a bonding layer. In that case, the bonding layer may be one of a solder bump of a Sn-series, a solder bump of a In-series, a conductive adhesive, and a liquid crystal polymer. The thickness of the bonding layer is less than about 1 μm.

According to a preferred embodiment of the present invention, the light-emitting element is a semiconductor laser device having a light-emitting element of a ridge-shape and the metal column that encloses the light-emitting part is of a ridge-shape.

According to an aspect of the present invention, there is provided a flip-chip bonding structure of a light-emitting element, which includes: a light-emitting element; a sub-mount; a metal column for connecting the light-emitting element with the sub-mount electrically and thermally; and metal pad layers interposed between the light-emitting element and the metal column, and between the sub-mount and the metal column, thereby improving an adhesive efficiency with respect to the metal column, wherein the thermal conductivity of the metal column is greater than that of the sub-mount.

The light-emitting element is one of a laser diode (LD) and a light-emitting diode (LED).

According to the present invention, the metal pad layer between the light-emitting element and the metal column may be divided into a first and second metal pad layers electrically connected with a p-type electrode and an n-type electrode of the light-emitting element, respectively. The metal pad layer between the sub-mount and the metal column is divided into a third and a fourth metal pad layers that correspond to the first and the second metal pad layers, respectively. The metal column is divided into a first metal column between the first and the third metal pad layers and a second metal column between the second and the fourth metal pad layers.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic, cross-sectional view of a bonding structure of a light-emitting element using a wire according to a related art;

FIG. 2 is a cross-sectional view of a flip-chip bonding structure of a light-emitting element using a solder bump according to a related art;

FIG. 3A is a cross-sectional view illustrating a light-emitting element portion in a flip-chip bonding structure of a light-emitting element according to the present invention;

FIG. 3B is a cross-sectional view illustrating a sub-mount portion in a flip-chip bonding structure of a light-emitting element according to the present invention;

FIG. 4 is a cross-sectional view illustrating an overall structure of a light-emitting element that is flip-chip bonded according to the present invention;

FIG. 5 is an enlarged, cross-sectional view of a ridge portion of a compound semiconductor light-emitting element; and

FIG. 6 is a graph comparatively illustrating temperatures of a p-type electrode in a flip-chip bonding structure of a light-emitting element according to the present invention and a flip-chip bonding structure of a related art.

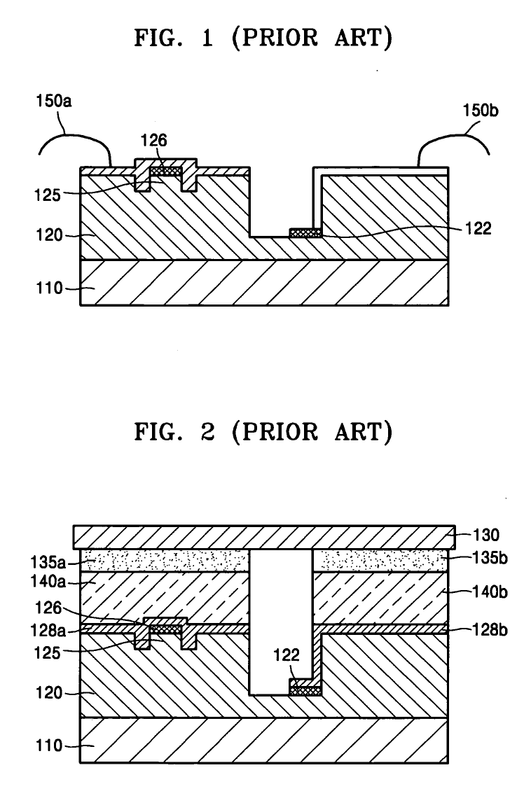

### DETAILED DESCRIPTION OF THE EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein.

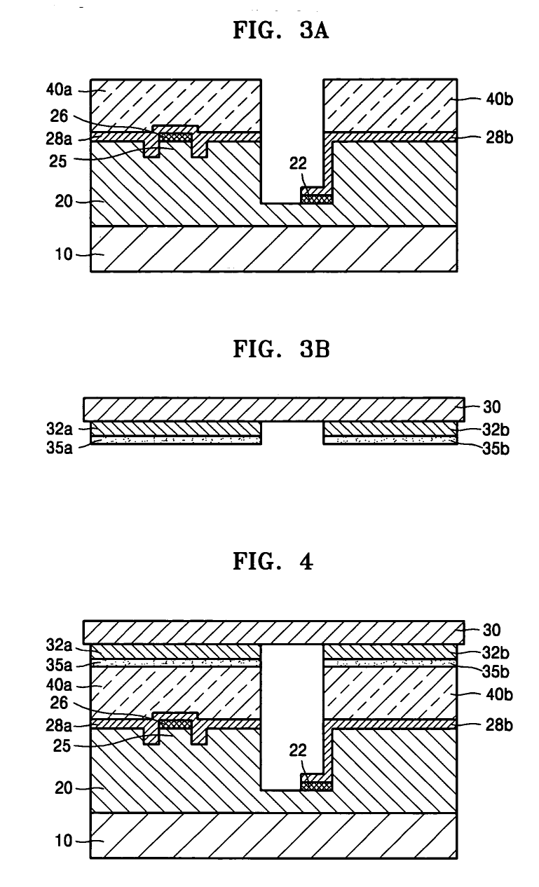

FIGS. 3A and 3B are cross-sectional views illustrating a light-emitting element portion and a sub-mount portion in a flip-chip bonding structure of a light-emitting element according to the present invention.

First, referring to FIG. 3A, first and second metal pad layers 28a and 28b are formed respectively on a light-emitting element 20 formed on a sapphire substrate 10. Metal columns 40a and 40b are formed respectively on the first and the second metal pad layers 28a and 28b. The light-emitting element 20 exemplarily shown in FIG. 3A is an edge-emitting type semiconductor laser device, where a laser beam is emitted in a direction perpendicular to the drawing from a light-emitting part 25 of a ridge shape. However, the light-emitting element 20 of the present invention can be a semiconductor light-emitting element such as an LD and an LED of other types.

The first and the second metal pad layers 28a and 28b are provide efficient adhesion to the metal columns 40a and 40b formed thereon. As described above, the first and the second metal pad layers 28a and 28b can be a structure wherein a Ti-film, a Pt-film, and an Au-film are sequentially stacked. As illustrated, the first metal pad layer 28a is formed on a region of one side of the light-emitting element 20 and electrically contacts a p-type electrode 26 on the light-emitting part 25, and encloses the light-emitting part 25 of the ridge shape. Further, the second metal pad layer 28b is formed on a region of the other side of the light-emitting element 20 and electrically contacts an n-type electrode 22. However, if electrodes are formed respectively on an upper surface of the light-emitting element 20 and the electrodes can be directly bonded to the metal columns 40a and 40b, the first and the second metal pad layers 28a and 28b can be omitted.

The first and the second metal columns 40a and 40b bond the light-emitting element to the sub-mount in substitution for the solder bump of the related art and provide an electrical and thermal path between the light-emitting element and the sub-mount. Therefore, the metal columns 40a and 40b may be made of conductive metal having a high thermal conductivity. Particularly, the metal columns 40a and 40b may have a thermal conductivity greater than a thermal conductivity of the sub-mount in order to provide an efficient heat emission path. For the conductive metal, Cu, Ag, and Au can be used. For example, Cu has a thermal conductivity of about 400 mK/cm² which is relatively high and greater than the 250 mK/cm² of AlN primarily used for the sub-mount. Therefore, it is possible to provide a natural heat emission path such that the thermal conductivity is high in the vicinity closest to the light-emitting part which generates much heat and the thermal conductivity is gradually lowered elsewhere.

In this aspect, the first metal column 40a formed on the light-emitting part 25 plays a particularly important role. As illustrated, the first metal column 40a encloses the light-emitting part 25 of a ridge shape together with the first metal pad layer 28a. If the first metal pad layer 28a is omitted, the first metal column 40a directly encloses the light-emitting part 25. On the contrary, since the second metal column 40b has a relatively small influence on the heat emission path, other metal can be used besides the above-mentioned metal. Though the thicknesses of the first and the second metal columns 40a and 40b may be different depending on the sizes of the light-emitting element and the sub-mount that are actually used, the the thicknesses commonly may be about 4-5 μm.

Next, referring to FIG. 3B, a third and a fourth metal pad layers 32a and 32b are separately formed under the sub-mount 30. The third and the fourth metal pad layers 32a and 32b correspond to the first and the second metal pad layers 28a and 28b on the light-emitting element 20, respectively. Like the first and the second metal pad layers 28a and 28b, the third and the fourth metal pad layers 32a and 32b can be also a structure where a Ti-film, a Pt-film, and an Au-film are sequentially stacked.

Further, first and second bonding layers 35a and 35b can be formed on the third and the fourth metal pad layers 32a and 32b in an embodiment. The first bonding layer 35a is intended for bonding the third metal pad layer 32a and the first metal column 40a. The second bonding layer 35b is intended for bonding the fourth metal pad layer 32b and the second metal column 40b. For the first and the second bonding layers 35a and 35b, a solder bump of the Sn-series, a solder bump of the In-series, a conductive adhesive, and liquid crystal polymer can be exemplarily used. As described above, SnAg, PbSn, and AuSn can be used for the solder bump of Sn-series. At this point, the bonding layers 35a and 35b may be minimized in their thickness so that the thickness will not have an influence on the thermal conductivity and the electrical conductivity between the metal columns 40a and 40b and the sub-mount 30. For example, the thickness of the first and the second bonding layers 35a and 35b may be less than about 1 μm.

With the above-described structure, the first and the second metal columns 40a and 40b of FIG. 3A are bonded to the third and the fourth metal pad layers 32a and 32b of FIG. 3B, respectively, using the first and the second bonding layers 35a and 35b of FIG. 3B, so that a bonding between the light-emitting element 20 and the sub-mount 30 is as illustrated in FIG. 4. When using the solder bumps for the first and the second bonding layers 35a and 35b, a bonding between the first and the second metal columns 40a and 40b and the third and the fourth metal pad layers 32a and 32b is performed by melting the solder bumps. Further, when using a conductive adhesive or liquid crystal polymer for the first and the second bonding layers 35a and 35b, the conductive adhesive or the liquid crystal polymer is applied to a surface of the third and the fourth metal pad layers 32a and 32b. Then, after the first and the second metal columns 40a and 40b are pressed beneath the third and the fourth metal pad layers 32a and 32b, the conductive adhesive or the liquid crystal polymer is hardened, so that bonding is achieved.

Also, it is possible to directly bond the first and the second metal columns 40a and 40b to the third and the fourth metal pad layers 32a and 32b, respectively, using the known sonic bonding methods without using the first and the second bonding layers 35a and 35b. In that case, metal layers with which the sonic bonding can be performed can be provided between the first and the second metal columns 40a and 40b and the third and the fourth metal pad layers 32a and 32b so that the sonic bonding may be easily performed. For such metal layers, Au, Cu can be used.

FIG. 4 is a cross-sectional view illustrating an overall structure after the light-emitting element 20 is flip-chip bonded to the sub-mount 30 according to the present invention. The primary heat generation source in the light-emitting element 20 is the light-emitting part 25. Heat generated from the light-emitting part 25 flows through the first metal pad layer 28a, the first metal column 40a, the first bonding layer 35a, the third metal pad layer 32a, and is finally is discharged through the sub-mount 30. In case the sonic bonding is performed, a metal layer of Au or Cu can be used instead of the first bonding layer 35a. The first metal column 40a whose thickness is about 4-5 μm occupies the largest portion of the heat emission path and other parts have smaller influences on the heat emission path since their thicknesses are relatively small. As described above, since the first metal column 40a that employs Cu, Ag, and Au has a large thermal conductivity, the heat emission efficiency is increased compared to the related art. Particularly, since the first metal column 40a has the thermal conductivity larger than the thermal conductivity of the sub-mount 30 which mainly uses AlN, it is possible to create an efficient heat emission path such that the thermal conductivity is gradually reduced from a heat source to a final heat emission point.

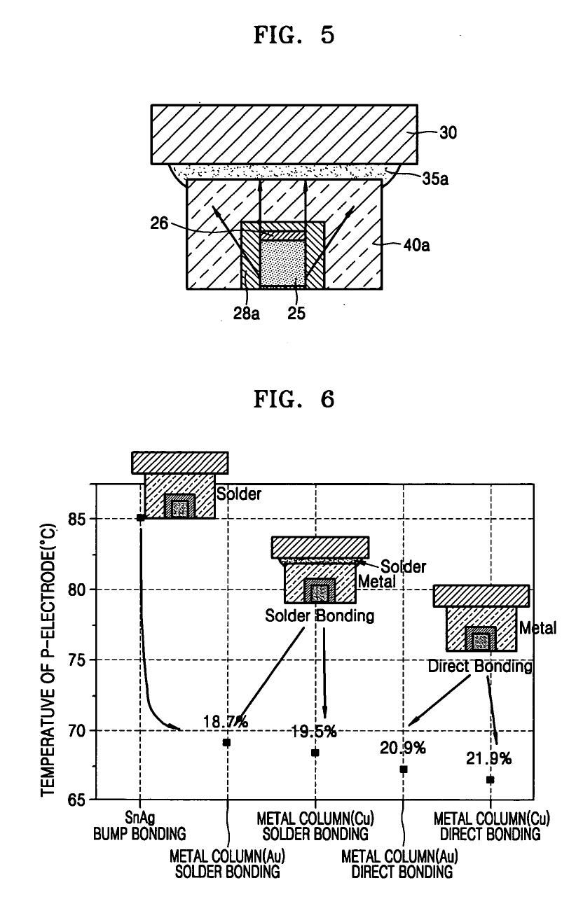

FIG. 5 is an enlarged, cross-sectional view of a compound semiconductor laser light-emitting element having a ridge shape that can be used as the light-emitting element 20. Referring to FIG. 5, the first metal pad layer 28a and the first metal column 40a enclose and surround the protruded light-emitting part 25 of a ridge shape and a p-type electrode 26 on the light-emitting part 25. Thereby, heat generated from the light-emitting part 25 is transferred to the first metal pad layer 28a and the first metal column 40a through three planes of the light-emitting part 25. Since there exists many heat transfer planes as described above, the heat generated from the light-emitting part 25 can be swiftly emitted. Also, since the first bonding layer 35a is formed very thinly around the first metal column 40a, the first bonding layer 35a does not hinder the heat emission to any significant degree.

FIG. 6 is a graph comparatively illustrating temperatures of a p-type electrode having a flip-chip bonding structure of a light-emitting element according to the present invention and a flip-chip bonding structure of a related art. As indicated in FIG. 6, when the light-emitting element is flip-chip bonded using a solder bump of SnAg in accordance with the related art, a temperature of the p-type electrode 26 on the light-emitting part 25 is about 85° C. On the contrary, in case Au is used for the first metal column 40a and a solder is used for the first bonding layer 35a, the temperature of the p-type electrode 26 is about 69° C. and thus a temperature reduction effect of about 18.7% can be obtained. Further, in case Cu is used for the first metal column 40a and a solder is used for the first bonding layer 35a, the temperature of the p-type electrode 26 is about 68° C. and thus a temperature reduction effect of about 19.5% can be obtained. In the meantime, in case a direct bonding is performed using the sonic bonding method without an intermediate bonding layer, the temperatures of the p-type electrode 26 are about 67° C. or 66° C., respectively, depending on whether the first metal column 40a is Au or Cu. Therefore, for these cases, the temperature reduction effects of 20.9% and 21.9% can be obtained, respectively.

As described above, according to the present invention, since the heat emission path is such that the thermal conductivity is gradually reduced from the heat source to the final heat emission point, the heat emission efficiency is increased. Particularly, since the metal column having a very large thermal conductivity is used instead of the solder bump, the heat generated from the heat source of the light-emitting element such as the ridge of the semiconductor laser diode can be swiftly emitted.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A flip-chip bonding structure of a light-emitting element, comprising:
a light-emitting element:
a sub-mount; and
a metal column connecting the light-emitting element with the sub-mount electrically and thermally.

2. The structure of claim 1, wherein a thermal conductivity of the metal column is greater than that of the sub-mount.

3. The structure of claim 2, wherein the metal column comprises at least one of metal selected from the group consisting of Au, Ag, and Cu.

4. The structure of claim 2, further comprising metal pad layers interposed between the light-emitting element and the metal column, and between the sub-mount and the metal column, improving an adhesive efficiency with respect to the metal column.

5. The structure of claim 4, wherein the metal pad layer between the light-emitting element and the metal column is electrically connected with an electrode of the light-emitting element.

6. The structure of claim 2, wherein the metal column is directly bonded to the sub-mount using a sonic bonding method.

7. The structure of claim 2, wherein the metal column is bonded to the sub-mount using a bonding layer.

8. The structure of claim 7, wherein the bonding layer is selected from the group consisting of a solder bump of the Sn-series, a solder bump of the In-series, a conductive adhesive, and a liquid crystal polymer.

9. The structure of claim 7, wherein a thickness of the bonding layer is less than about 1 μm.

10. The structure of claim 2, wherein the light-emitting element is a semiconductor LD (laser diode) having a light-emitting part of a ridge shape and the metal column encloses the light-emitting part and has a ridge shape.

11. A flip-chip bonding structure of a light-emitting element, comprising:
a light-emitting element;
a sub-mount;
a metal column for connecting the light-emitting element with the sub-mount electrically and thermally; and
metal pad layers interposed between the light-emitting element and the metal column, and between the sub-mount and the metal column, improving an adhesive efficiency with respect to the metal column,
wherein the thermal conductivity of the metal column is greater than that of the sub-mount.

12. The structure of claim 11, wherein the metal column comprises at least one of metal selected from the group consisting of Au, Ag, and Cu.

13. The structure of claim 11, wherein the light-emitting element is one of an LD (laser diode) and an LED (light-emitting diode).

14. The structure of claim 13, wherein the metal pad layer between the light-emitting element and the metal column is divided into a first metal pad layer and a second metal pad layer electrically connected with a p-type electrode and an n-type electrode of the light-emitting element, respectively;
the metal pad layer between the sub-mount and the metal column is divided into a third pad layer and a fourth pad layer that correspond to the first metal pad layer and the second metal pad layer, respectively; and
the metal column is divided into a first metal column between the first and the third metal pad layers and a second metal column between the second and the fourth metal pad layers.

15. The structure of claim 14, wherein the first and the second metal columns are directly bonded to the third and the fourth metal pad layers, respectively, using a sonic bonding method.

16. The structure of claim 15, wherein metal layers for use in the sonic bonding method are respectively formed between the first metal column and the third metal pad layer, and between the second metal column and the fourth metal pad layer.

17. The structure of claim 16, wherein the metal layer comprises at least one of Au and Cu.

18. The structure of claim 14, wherein the first and the second metal columns are bonded to the third and the fourth metal pad layers, respectively, using a bonding layer.

19. The structure of claim 18, wherein the bonding layer is selected from the group consisting of a solder bump of the Sn-series, a solder bump of the In-series, a conductive adhesive, and a liquid crystal polymer.

20. The structure of claim 19, wherein a thickness of the bonding layer is less than about 1 μm.

21. The structure of claim 13, wherein the light-emitting element is a semiconductor LD (laser diode) having a light-emitting part of a ridge shape and the metal column encloses the light-emitting part and has a ridge shape.
